(19) United States
(12) Patent Application Publication
(10) Pub. No.: US 2011/0085578 A1
(43) Pub. Date: Apr. 14, 2011

(54) SEMICONDUCTOR DEVICE AND METHOD FOR MANUFACTURING THE SAME

(75) Inventors: Seiichi Tokunaga, Osaka (JP); Kunio Takeuchi, Kyoto (JP)

(73) Assignee: SANYO ELECTRIC CO., LTD., Moriguchi-shi (JP)

(21) Appl. No.: 12/970,027

(22) Filed: Dec. 16, 2010

Related U.S. Application Data
(63) Continuation of application No. 12/123,660, filed on May 20, 2008.

(30) Foreign Application Priority Data
May 24, 2007 (JP) 2007-137932

(51) Int. Cl. H01S 5/22; H01L 33/32

(52) U.S. Cl. 372/45.01; 257/103; 257/E33.025

(57) ABSTRACT

In a blue-violet semiconductor laser device, a pair of side surfaces of a semiconductor device structure composed of a nitride based semiconductor layer is respectively positioned inside a pair of side surfaces of a partial substrate composed of a Ge substrate. This causes the pair of side surfaces of the semiconductor device structure and the pair of side surfaces of the partial substrate to be respectively spaced apart from each other by a predetermined distance in a direction perpendicular to the pair of side surfaces of the semiconductor device structure. On the partial substrate, current blocking layers are formed in a region between the pair of side surfaces of the partial substrate and the pair of side surfaces of the semiconductor device structure.

### BACKGROUND OF THE INVENTION

1. Field of the Invention

The present invention relates to a semiconductor device having a compound semiconductor layer and a method for manufacturing the same.

2. Description of the Background Art

In recent years, DVDs (Digital Versatile Disks) that can be recorded and reproduced using blue-violet light beams having wavelengths of approximately 405 nm have been put to practical use. In order to record and reproduce such DVDs, DVD drives using semiconductor laser devices that emit blue-violet light beams having wavelengths of approximately 405 nm (blue-violet semiconductor laser devices) have been also put to practical use.

The blue-violet semiconductor laser devices are produced by forming nitride based semiconductor layers on substrates such as GaN (gallium nitride) substrates or sapphire substrates, for example.

The GaN substrates are preferably used as substrates for forming the nitride based semiconductor layers. When the nitride based semiconductor layers are formed on the GaN substrates, strains and crystal defects occurring in the nitride based semiconductor layers when the nitride based semiconductor layers are formed can be reduced, as compared with those in cases where the nitride based semiconductor layers are formed on the other substrates such as the sapphire substrates. Therefore, high-power blue-violet semiconductor laser devices having high reliabilities can be obtained by using the GaN substrates.

However, the GaN substrates are higher in cost, as compared with the other substrates (e.g., the sapphire substrates) on which the nitride based semiconductor layers can be formed.

Therefore, JP 2005-93988 A discloses a method for manufacturing a semiconductor light emitting device that can repeatedly utilize a GaN substrate as a substrate for growth of a nitride based semiconductor layer. In the manufacturing method, a release layer having a band gap energy lower than that of the GaN substrate is formed on the GaN substrate serving as the substrate for growth. Furthermore, the nitride based semiconductor layer is formed on the release layer. Thereafter, the release layer is irradiated through the GaN substrate with a laser beam having an energy higher than the band gap energy of the release layer and lower than the band gap energy of the GaN substrate. This causes the GaN substrate to be separated from the nitride based semiconductor layer (laser lift-off).

FIGS. 10 and 11 are schematic sectional views showing an example of processes for manufacturing a conventional blue-violet semiconductor laser device. In FIGS. 10 and 11, the processes for manufacturing the blue-violet semiconductor laser device are illustrated with vertical sectional views.

A GaN substrate 50 is first prepared, and a release layer 51 and an underlying layer 52 are formed on one surface of the GaN substrate 50, as shown in FIG. 10 (a). Furthermore, a nitride based semiconductor layer 10 including an active layer is formed on the underlying layer 52.

A plurality of striped ridges Ri are formed on an upper surface of the nitride based semiconductor layer 10. FIG. 10 illustrates two ridges Ri. Furthermore, ohmic electrodes 17 are formed on respective upper surfaces of the ridges Ri, and an insulating layer 21 composed of SiO₂ (silicon oxide) is formed in a region on respective side surfaces of the ridges Ri and the nitride based semiconductor layer 10 excluding the ridges Ri.

Then, a Ge (germanium) substrate 42 having a contact electrode 41 formed on its one surface is prepared, and a fusion layer 30 is formed on the contact electrode 41 on the Ge substrate 42, as shown in FIG. 10 (b). The nitride based semiconductor layer 10 is affixed to the fusion layer 30 with the ohmic electrode 17 or the insulating layer 21 sandwiched therebetween.

Then, the release layer 51 is irradiated through the GaN substrate 50 with laser beams LA, to thermally decompose the release layer 51 to separate the GaN substrate 50 from the nitride based semiconductor layer 10, as shown in FIG. 10 (c). Thus, the nitride based semiconductor layer 10 supported on the Ge substrate 42 is obtained, as shown in FIG. 11 (d).

Thereafter, an electrode layer 19 is formed on an exposed surface of the nitride based semiconductor layer 10, as shown in FIG. 11 (e). Then, scribe flaws are formed by laser scribing or diamond point scribing in the Ge substrate 42 through the nitride based semiconductor layer 10, as respectively indicated by arrows in FIG. 11 (f).

Finally, the Ge substrate 42 is separated by cleavage along the scribe flaws, and a back surface electrode 43 is formed on an exposed surface of the Ge substrate 42, as shown in FIG. 11 (g). This allows a plurality of blue-violet semiconductor laser devices 900 to be obtained.

On the other hand, JP 2005-12188 A discloses a manufacturing method in which a semiconductor device is separated by wet etching.

In the processes for manufacturing the blue-violet semiconductor laser device 900 described using FIGS. 10 and 11, therefore, it is considered that the blue-violet semiconductor laser device 900 is separated by wet etching.

### SUMMARY OF THE INVENTION

According to an aspect of the present invention, a semiconductor device includes a supporting substrate having a supporting surface and a pair of first side surfaces, a semiconductor layer provided on the supporting surface of the supporting substrate and having a pair of second side surfaces respectively positioned inside the pair of first side surfaces of the supporting substrate, and an insulating layer formed so as to cover a region of the supporting surface between the pair of first side surfaces of the supporting substrate and the pair of second side surfaces of the semiconductor layer.

The insulating layer may be formed so as to extend between the supporting substrate and the semiconductor layer.

The semiconductor device may further include a fusion layer formed between the supporting substrate and the semiconductor layer.

The insulating layer may be formed so as to extend between the fusion layer and the semiconductor layer.

The semiconductor layer may include a light emitting layer that emits a light beam.

The insulating layer may be formed on a side surface of the light emitting layer.

The semiconductor layer may have a projection on the side of the supporting substrate, and the light emitting layer may be formed in the projection.

The semiconductor layer may include a semiconductor layer of a first conductivity type and a semiconductor layer of a second conductivity type, on the side of the supporting substrate, on the semiconductor layer of a first conductivity type, and the insulating layer may be formed on a side surface of a junction between the semiconductor layer of a first conductivity type and the semiconductor layer of a second conductivity type.

The semiconductor layer may have a projection on the side of the supporting substrate, the semiconductor layer may include a semiconductor layer of a first conductivity type and a semiconductor layer of a second conductivity type, on the side of the supporting substrate, on the semiconductor layer of a first conductivity type, and the projection may include the semiconductor layer of a first conductivity type and the semiconductor layer of a second conductivity type.

The light emitting layer may include a cavity that performs lasing.

The semiconductor layer may include a second semiconductor layer, on the side of the supporting substrate, on the light emitting layer, the second semiconductor layer may have a projection and flat portions on both sides of the projection, and the insulating layer may be formed in a side surface of the projection and the flat portions, excluding an upper surface of the projection.

The supporting substrate may further have a pair of third side surfaces crossing the pair of first side surfaces, the semiconductor layer may further have a pair of fourth side surfaces crossing the pair of second side surfaces and respectively positioned inside the pair of third side surfaces of the supporting substrate, and the insulating layer may be formed so as to cover a region of the supporting surface between the pair of third side surfaces of the supporting substrate and the pair of fourth side surfaces of the semiconductor layer.

The semiconductor layer may include a nitride based semiconductor.

The supporting substrate may be a germanium substrate.

According to another aspect of the present invention, a method for manufacturing a semiconductor device includes the steps of forming a semiconductor layer on a substrate for growth, forming an insulating layer on a predetermined region of the semiconductor layer, affixing the substrate for growth and a supporting substrate for supporting the semiconductor layer to each other with the insulating layer sandwiched there between, separating the substrate for growth from the semiconductor layer, removing a partial region of the semiconductor layer such that the insulating layer is exposed, to divide the semiconductor layer into a plurality of semiconductor device structures each having a pair of second side surfaces, and cutting the supporting substrate among the plurality of semiconductor device structures, to divide the supporting substrate into a plurality of partial substrates each having a pair of first side surfaces, in which the step of dividing the supporting substrate may include the step of cutting the supporting substrate such that the pair of second side surfaces of each of the semiconductor device structures is respectively positioned inside the pair of first side surfaces of each of the partial substrates and the insulating layer covers a region between the pair of first side surfaces of each of the partial substrates and the pair of second side surfaces of each of the semiconductor device structures.

The substrate for growth may be a gallium nitride substrate.

The step of forming the semiconductor layer on the substrate for growth may include the step of forming a release layer on the substrate for growth and forming the semiconductor layer on the release layer.

The step of dividing the semiconductor layer into the plurality of semiconductor device structures may include the step of dividing the semiconductor layer into a plurality of semiconductor device structures such that the insulating layer remains between the supporting substrate and the semiconductor layer.

The method for manufacturing the semiconductor device may further include the step of forming a projection in the semiconductor layer, and the step of forming the insulating layer on the predetermined region may include the step of forming an insulating film on an upper surface of the semiconductor layer and a side surface of the projection, excluding an upper surface of the projection.

The step of dividing the supporting substrate may include the step of forming a scribe groove by laser scribing.

Other features, elements, characteristics, and advantages of the present invention will become more apparent from the following description of preferred embodiments of the present invention with reference to the attached drawings.

### BRIEF DESCRIPTION OF THE DRAWINGS

FIG. 1 is a schematic process diagram for explaining a method for manufacturing a blue-violet semiconductor laser device according to a first embodiment;

FIG. 2 is a schematic process diagram for explaining a method for manufacturing the blue-violet semiconductor laser device according to the first embodiment;

FIG. 3 is a schematic process diagram for explaining a method for manufacturing the blue-violet semiconductor laser device according to the first embodiment;

FIG. 4 is a schematic process diagram for explaining a method for manufacturing the blue-violet semiconductor laser device according to the first embodiment;

FIG. 5 is a schematic sectional view and a top view showing the blue-violet semiconductor laser device according to the first embodiment;

FIG. 6 is a schematic process diagram for explaining a method for manufacturing a blue-violet LED according to a second embodiment;

FIG. 7 is a schematic process diagram for explaining a method for manufacturing the blue-violet LED according to the second embodiment;

FIG. 8 is a schematic process diagram for explaining a method for manufacturing the blue-violet LED according to the second embodiment;

FIG. 9 is a schematic sectional view and a top view showing the blue-violet LED according to the second embodiment;

FIG. 10 is a schematic sectional view showing an example of processes for manufacturing a conventional blue-violet semiconductor laser device; and

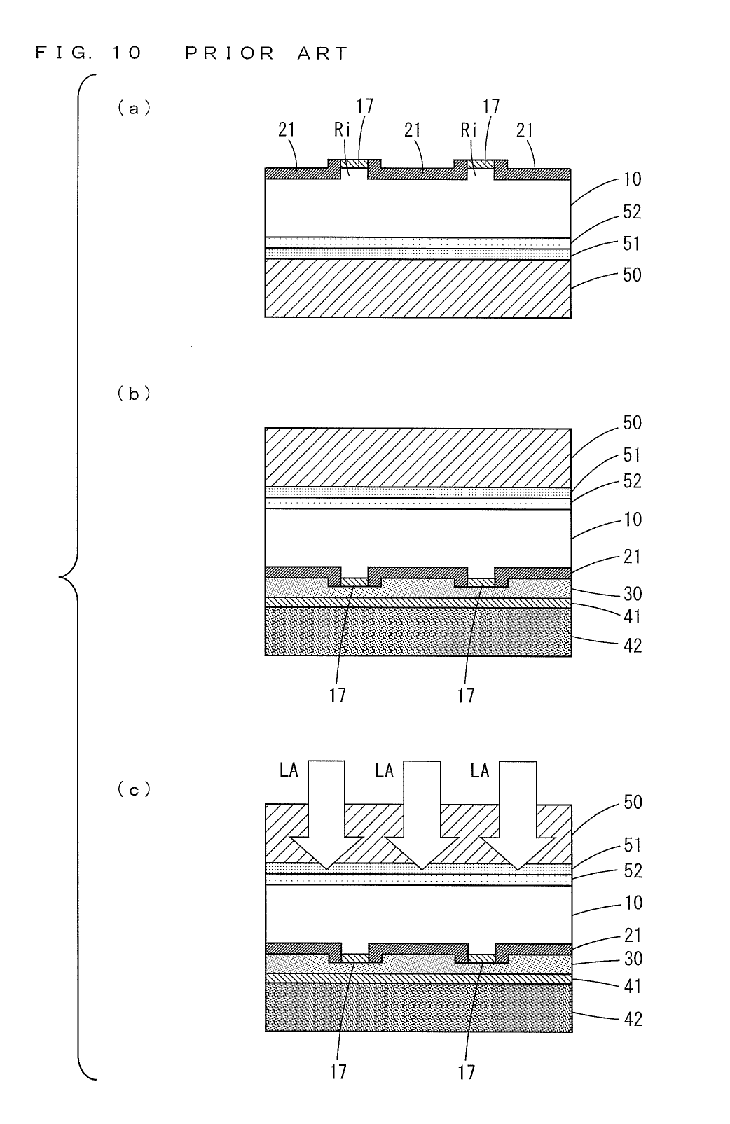

FIG. 11 is a schematic sectional view showing an example of processes for manufacturing the conventional blue-violet semiconductor laser device.

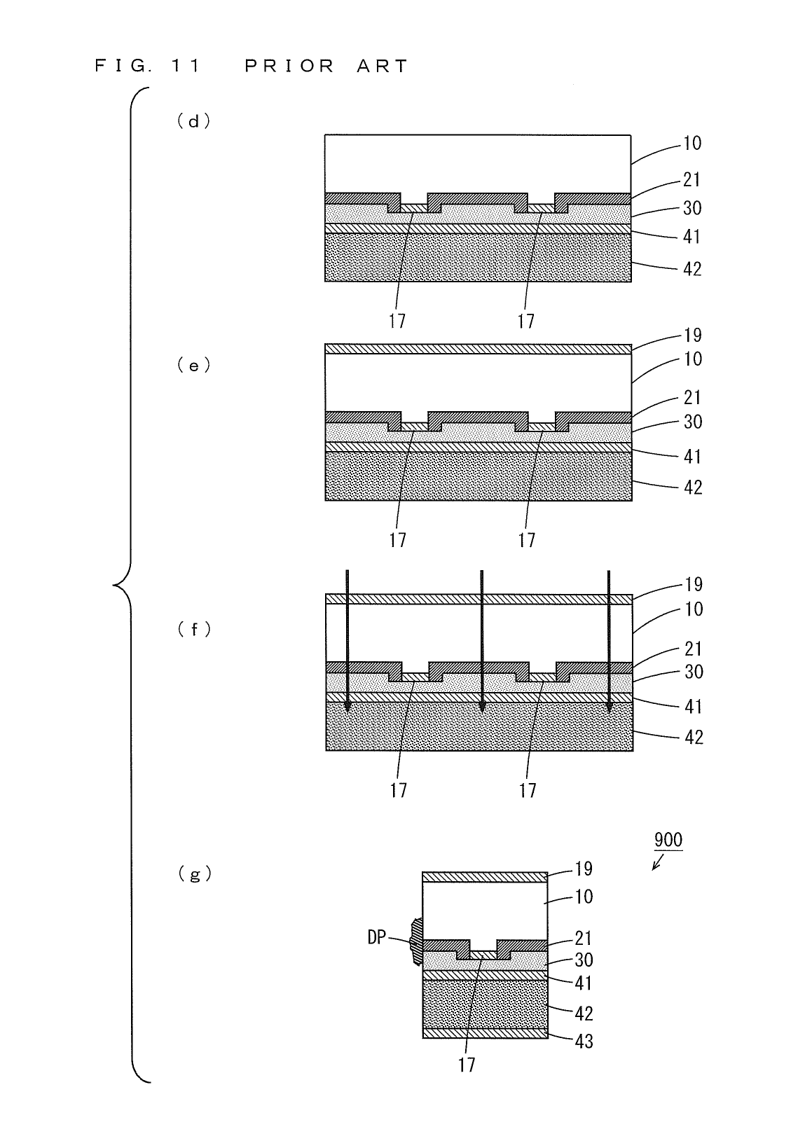

### DESCRIPTION OF THE PREFERRED EMBODIMENTS

### [1] First Embodiment

In the present embodiment, a semiconductor laser device that emits a laser beam having a wavelength of approximately 400 nm (hereinafter abbreviated as a blue-violet semiconductor laser device) as an example of a semiconductor device and a method for manufacturing the same will be described.

(1) Method for Manufacturing Semiconductor Laser Device

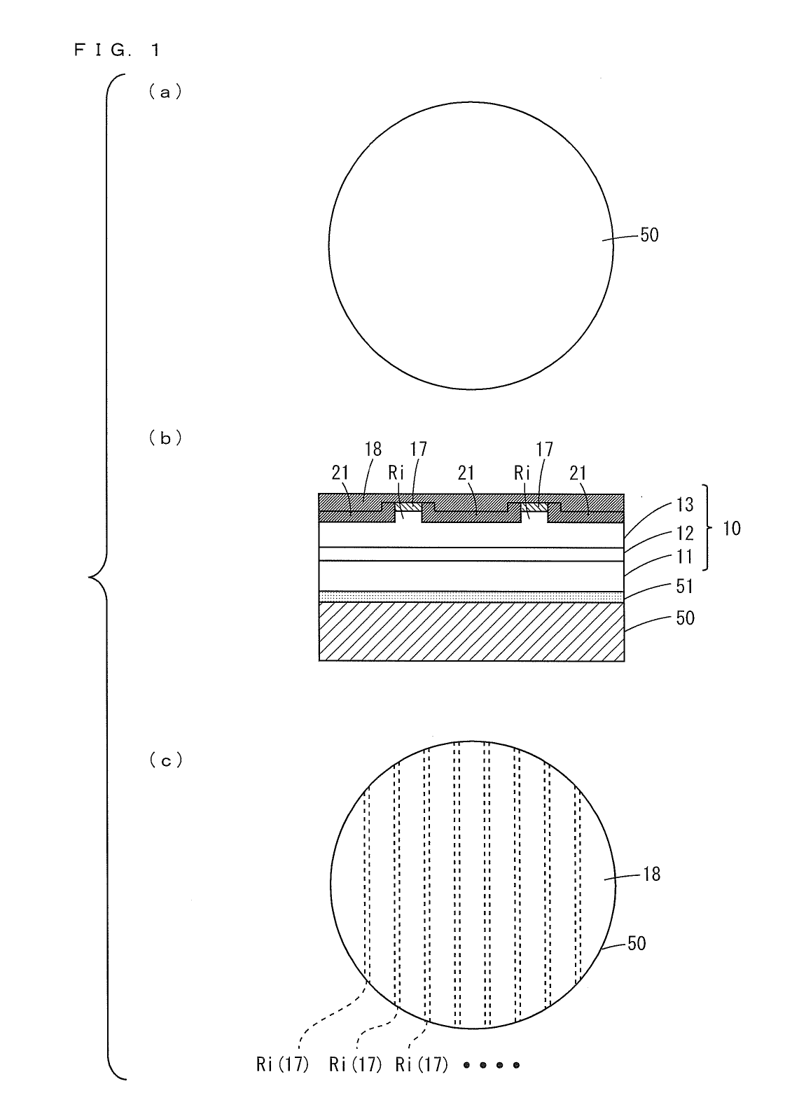

FIGS. 1 to 4 are schematic process diagrams for explaining the method for manufacturing the blue-violet semiconductor laser device according to the first embodiment.

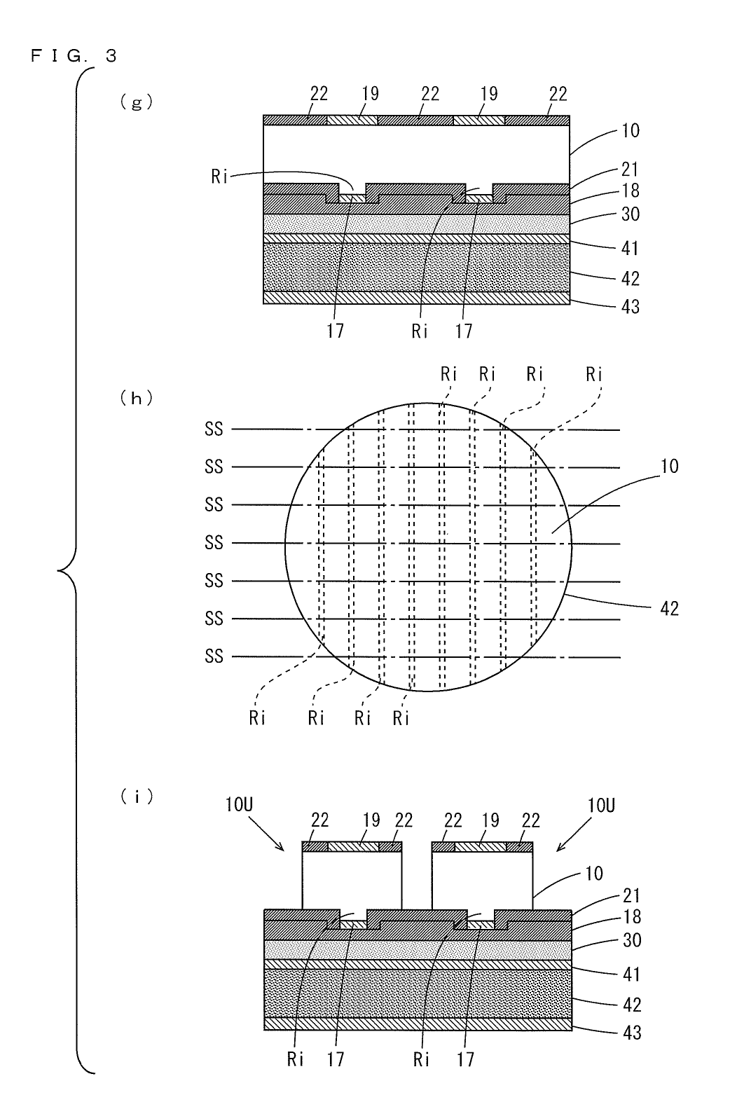

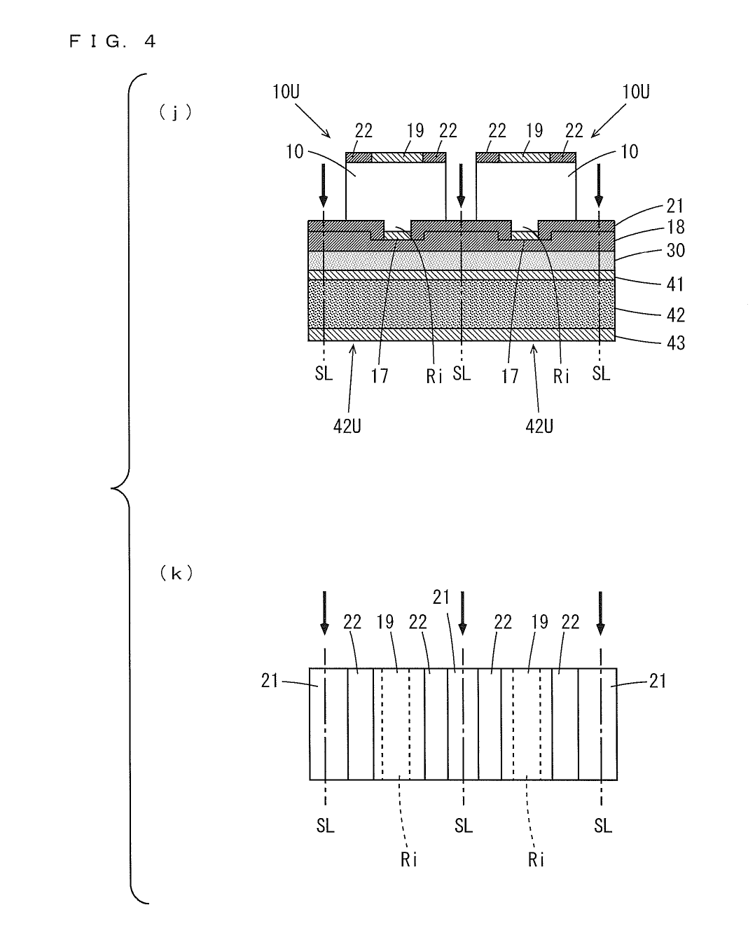

In FIGS. 1 to 4, FIGS. 1 (a) and 1 (c) and FIG. 3 (h) are top views of a substrate, FIGS. 3 (g) and 3 (i) and FIG. 4 (j) are schematic sectional views of a device structure, and FIG. 4 (k) is a top view of the device structure shown in FIG. 4 (j).

The blue-violet semiconductor laser device according to the present embodiment mainly has a configuration in which a Ge (germanium) substrate 42 and a nitride based semiconductor layer 10 are affixed to each other.

(1-a) Nitride Based Semiconductor Layer

First, the formation of the nitride based semiconductor layer 10 will be described. First, a GaN (gallium nitride) substrate 50 having a circular shape is prepared, as shown in FIG. 1 (a).

Then, a release layer 51 is formed on the prepared GaN substrate 50, and a first semiconductor layer 11, an active layer 12, and a second semiconductor layer 13 are grown in this order on the release layer 51 by MOCVD (Metal Organic Chemical Vapor Deposition), for example, as shown in FIG. 1 (b). Thus, the nitride based semiconductor layer 10 having a configuration in which the first semiconductor layer 11, the active layer 12, and the second semiconductor layer 13 are laminated is formed. The active layer 12 includes a cavity that performs lasing.

A plurality of ridges Ri are formed in a striped shape in the nitride based semiconductor layer 10. This causes the plurality of ridges Ri to be formed in a striped shape on the nitride based semiconductor layer 10 formed on the GaN substrate 50, as shown in FIG. 1 (c).

Thereafter, ohmic electrodes 17 and current blocking layers 21 are formed on the nitride based semiconductor layer 10. In this case, the current blocking layers 21 are formed on an upper surface of the nitride based semiconductor layer 10 and both side surfaces of the ridges Ri, excluding upper surfaces of the ridges Ri. Furthermore, a pad electrode 18 is formed on the ohmic electrodes 17 and the current blocking layers 21. Note that a SiO₂ (silicon oxide) film is formed as the current blocking layers 21 in the present embodiment.

(1-b) Ge Substrate

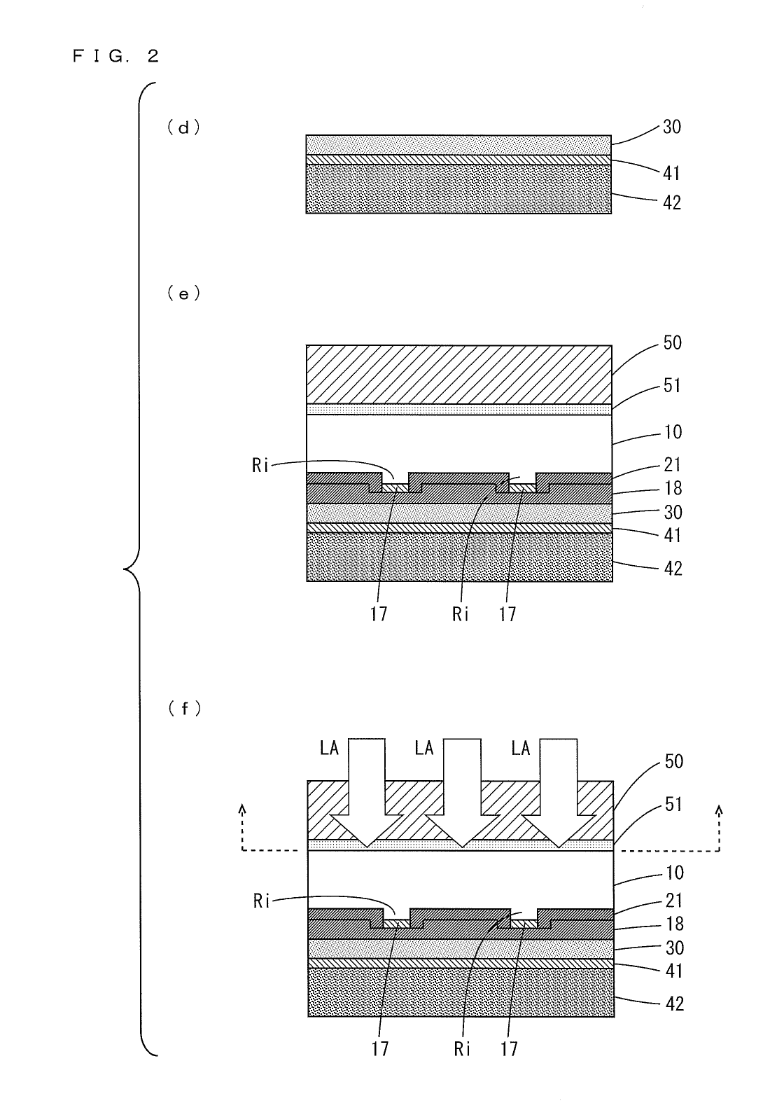

On the other hand, a Ge substrate 42 is prepared, as shown in FIG. 2 (d). The Ge substrate 42 has a circular shape having the same diameter as that of the GaN substrate 50 shown in FIG. 1 (a). A contact electrode 41 is formed on one surface of the Ga substrate 42. Furthermore, a fusion layer 30 is formed on the contact electrode 41.

(1-c) Affixation of Nitride Based Semiconductor Layer and Ge Substrate

Then, the nitride based semiconductor layer 10 shown in FIG. 1 (b) and the Ge substrate 42 shown in FIG. 2 (d) are affixed to each other by thermocompression bonding, as shown in FIG. 2 (e).

A solder composed of Au (gold) and Sn (tin), a solder composed of Au and Ge, or a conductive paste composed of Ag (silver), or the like can be used for the fusion layer 30 used in the thermocompression bonding.

(1-d) Separation of GaN Substrate

Then, a laminate of the nitride based semiconductor layer 10 and the Ge substrate 42 is irradiated through the GaN substrate 50 with laser beams LA, as shown in FIG. 2 (f). This causes a release layer 51 formed on one surface of the GaN substrate 50 to be decomposed by laser ablation while causing the GaN substrate 50 to be separated from the nitride based semiconductor layer 10 (see an arrow indicated by a dotted line in FIG. 2 (f)).

(1-e) Formation of Electrode

After the GaN substrate 50 is separated, electrodes 19 and insulating layers 22 are formed in a predetermined pattern on one surface of the nitride based semiconductor layer 10, as shown in FIG. 3 (g). Note that a SiO₂ film is formed as the insulating layers 22 in the present embodiment.

(1-f) Back Surface Electrode

A back surface electrode 43 is formed on the exposed other surface, on which the nitride based semiconductor layer 10 is not formed, of the Ge substrate 42.

(1-g) Separation of Device

Then, a plurality of scribe flaws are formed along scribe lines SS perpendicular to the ridges Ri by laser scribing or diamond point scribing, as shown in FIG. 3 (h). The Ge substrate 42 is separated in a stick shape by cleavage along the scribe flaws.

Here, a region including each of the ridges Ri and portions having a predetermined width on both sides thereof is referred to as a device region. Furthermore, a region having a predetermined width parallel to the ridge Ri between the adjacent device regions (hereinafter referred to as an inter-device region) is set.

Thereafter, the nitride based semiconductor layer 10 on the Ga substrate 42 separated in a stick shape is patterned, as shown in FIG. 3 (i). Specifically, a resist is applied on the electrode 19 and the insulating layer 22 that are formed on the nitride based semiconductor layer 10, to remove the resist in the inter-device regions. This causes the insulating layers 22 in the inter-device regions to be exposed. Exposed portions of the insulating layers 22 are removed using BHF (buffered hydrofluoric acid).

Furthermore, RIE (Reactive Ion Etching) is made within a Cl₂ (chlorine) based gas atmosphere, to remove the nitride based semiconductor layer 10 in the inter-device regions such that the current blocking layers 21 remain between the Ge substrate 42 and the nitride based semiconductor layer 10. This causes one surface of the current blocking layers 21 to be exposed in the inter-device regions. In such a way, a plurality of semiconductor device structures 10U are produced.

Then, a plurality of scribe flaws reaching the Ge substrate 42 from the exposure surface of the current blocking layer 21 are respectively formed along scribe lines SL at the centers in the inter-device regions by laser scribing or diamond point scribing (see arrows indicated by thick lines). The Ge substrate 42 is cleaved along the scribe flaws using a cleavage device. In such a way, a plurality of partial substrates 42U are produced. This causes the Ge substrate 42 to be separated in a device unit composed of the semiconductor device structure 10U and the partial substrate 42U.

(2) Configuration of Semiconductor Laser Device

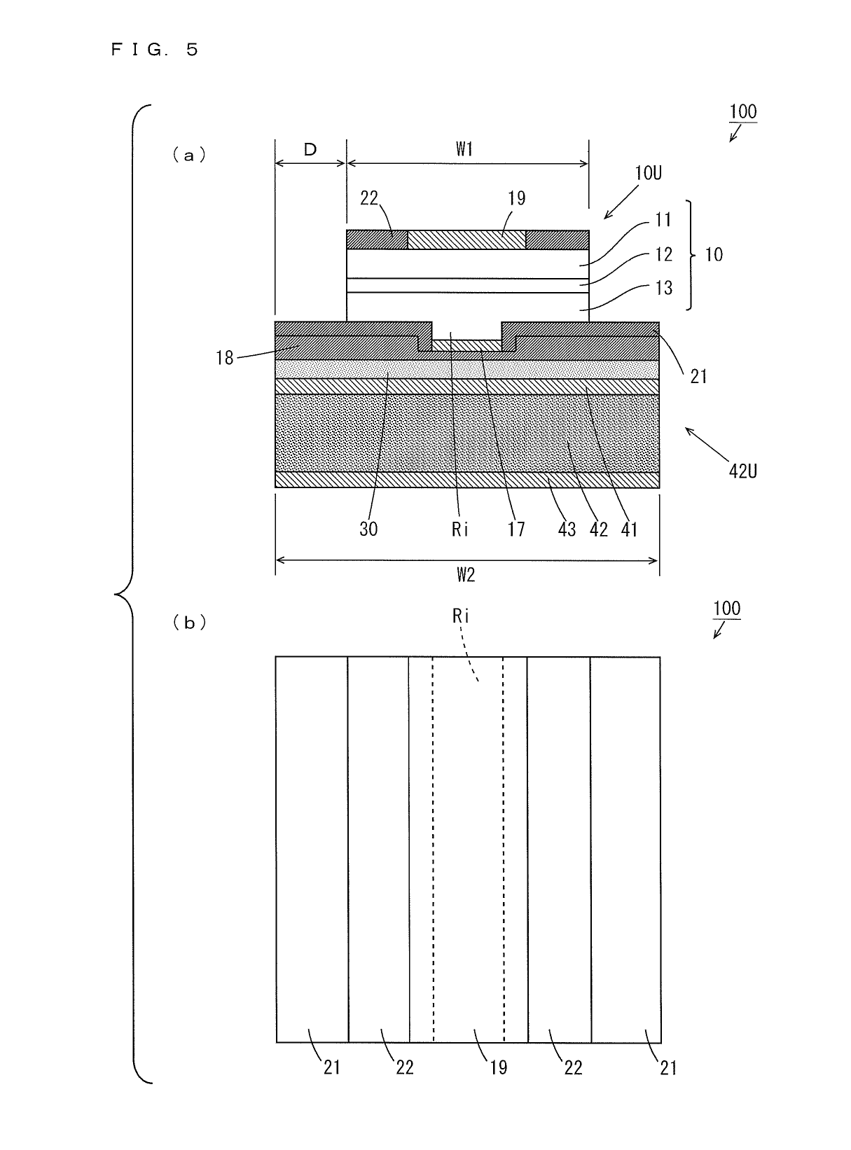

FIGS. 5 (a) and 5 (b) are respectively a schematic sectional view and a top view showing the blue-violet semiconductor laser device 100 according to the first embodiment. In the blue-violet semiconductor laser device 100, a voltage is applied to an area between the electrode 19 and the back surface electrode 43, so that a laser beam having a wavelength of approximately 400 nm is emitted from a region (a light-emitting point) above the ridge Ri in the active layer 12.

As described in the foregoing, when the blue-violet semiconductor laser device 100 according to the present embodiment is manufactured, the nitride based semiconductor layer 10 in the inter-device regions is removed before the device is separated along the scribe lines SL.

Thus, in the blue-violet semiconductor laser device 100, the size of the nitride based semiconductor layer 10 and the size of the Ge substrate 42 differ, as shown in FIGS. 5 (a) and 5 (b). Specifically, the width W1 of the nitride based semiconductor layer 10 is made smaller than the width W2 of the Ge substrate 42 in a direction parallel to the Ge substrate 42 and perpendicular to the ridge Ri in the nitride based semiconductor layer 10.

Therefore, steps consisting of upper surfaces of the current blocking layers 21 on both sides of the nitride based semiconductor layer 10 and upper surfaces of the insulating layers 22 on the nitride based semiconductor layer 10 is formed.

The current blocking layers 21 are respectively formed so as to cover regions on an upper surface of the semiconductor device structure 10U between both side surfaces of the partial substrate 42U and both side surfaces of the semiconductor device structure 10U. Furthermore, the current blocking layers 21 are formed so as to extend between the Ge substrate 42 and the nitride based semiconductor layer 10.

The fusion layer 30 is formed between the Ge substrate 42 and the nitride based semiconductor layer 10. Thus, the current blocking layers 21 are formed so as to extend between the fusion layer 30 and the nitride based semiconductor layer 10.

The nitride based semiconductor layer 10 includes a second semiconductor layer 13, on the side of the Ge substrate 42, on the active layer 12. The second semiconductor layer 13 has a ridge Ri and flat portions on both sides thereof. The current blocking layers 21 are respectively formed on side surfaces of the ridge Ri and the flat portions, excluding an upper surface of the ridge Ri. That is, the current blocking layers 21 are formed so as to extend in a region excluding the upper surface of the ridge Ri.

In the present embodiment, in a direction perpendicular to the ridge Ri, it is preferable that the distance D between the side surface of the nitride based semiconductor layer 10 and a side surface of the fusion layer 30 is set to not less than approximately 5 μm nor more than approximately 50 μm.

(3) Correspondences Between Elements in the Claims and Parts in Embodiments

In the first embodiment, the blue-violet semiconductor laser device 100 is an example of a semiconductor device, the Ge substrate 42 or the partial substrate 42U is an example of a supporting substrate, the nitride based semiconductor 10 or the semiconductor device structure 10U is an example of a semiconductor layer, the current blocking layer 21 is an example of an insulating layer, and the fusion layer 30 is an example of a fusion layer. The active layer 12 is an example of alight emitting layer, the ridge Ri is an example of a projection, and the second semiconductor layer 13 is an example of a second semiconductor layer.

Furthermore, the GaN substrate 50 is an example of a substrate for growth, and the release layer 51 is an example of a release layer.

(4) Effect of First Embodiment

(4-a)

In the semiconductor device according to the present embodiment, the supporting substrate has a supporting surface and a pair of first side surfaces. The semiconductor layer is provided on the supporting surface of the supporting substrate. The semiconductor layer has a pair of second side surfaces.

The pair of second side surfaces of the semiconductor layer is respectively positioned inside the pair of first side surfaces of the supporting substrate. This causes the pair of second side surfaces of the semiconductor layer and the pair of first side surfaces of the supporting substrate to be respectively spaced apart from each other by a predetermined distance in a direction perpendicular to the pair of second side surfaces of the semiconductor layer. Furthermore, the insulating layer is formed so as to cover a region of the supporting surface between the pair of first side surfaces of the supporting substrate and the pair of second side surfaces of the semiconductor layer. Even when a melt formed by heat generated when the semiconductor device is operated adheres to the pair of first side surfaces of the supporting substrate and the pair of second side surfaces of the semiconductor layer, therefore, the side surface of the supporting substrate and the side surface of the semiconductor layer are prevented from being electrically short-circuited by the melt. As a result, defective insulation is sufficiently inhibited from occurring when the semiconductor device is operated.

The fusion layer is formed between the supporting substrate and the semiconductor layer. In this case, even when a part of the fusion layer is melted by heat generated when the semiconductor device is operated, and the melt adheres to the pair of first side surfaces of the supporting substrate and the pair of second side surfaces of the semiconductor layer, the side surface of the supporting substrate and the side surface of the semiconductor layer are prevented from being electrically short-circuited by the melt. As a result, defective insulation is sufficiently inhibited from occurring when the semiconductor device is operated.

Since the insulating layer is formed so as to extend between the fusion layer and the semiconductor layer, the fusion layer is prevented from being detoured along the side surface of the semiconductor device.

The semiconductor layer includes a light emitting layer that emits a light beam. In this case, even when a melt formed by heat generated by the light emitting layer when the semiconductor device is operated adheres to the pair of first side surfaces of the supporting substrate and the pair of second side surfaces of the semiconductor layer, the side surface of the supporting substrate and the side surface of the semiconductor layer are prevented from being electrically short-circuited by the melt. As a result, defective insulation is sufficiently inhibited from occurring when the light beam is emitted.

The insulating layer is formed on a side surface of the light emitting layer. In this case, a leak current flowing after being detoured along the side surface of the light emitting layer can be restrained.

The light emitting layer includes a cavity that performs lasing. In this case, the semiconductor device is operated so that lasing is performed within the cavity, and a laser beam is emitted from its cavity facet.

Even when a melt formed by heat generated by the lasing when the semiconductor device is operated adheres to the pair of first side surfaces of the supporting substrate and the pair of second side surfaces of the semiconductor layer, the side surfaces of the supporting substrate and the side surfaces of the semiconductor layer are prevented from being electrically short-circuited by the melt. As a result, defective insulation is sufficiently inhibited from occurring when the laser beam is emitted.

The semiconductor layer includes a second semiconductor layer, on the side of the supporting substrate, on the light emitting layer, the second semiconductor layer has a projection and flat portions on both sides of the projection, and the insulating layer is formed on a side surface of the projection and the flat portions, excluding an upper surface of the projection. This allows the insulating layer to function as a current blocking layer. Although the insulating layer functioning as the current blocking layer is formed of a single insulating layer in the present embodiment, the insulating layer in the present invention may be formed of a plurality of insulating layers.

The semiconductor layer includes a nitride based semiconductor. In this case, the heat resistance of the semiconductor device is improved.

In the method for manufacturing the semiconductor device according to the present embodiment, the semiconductor layer is formed on the substrate for growth, the insulating layer is formed on a predetermined region of the semiconductor layer, and the substrate for growth and the supporting substrate are affixed to each other with the insulating layer sandwiched therebetween. Then, the substrate for growth is separated from the semiconductor layer, and the semiconductor layer in a partial region is removed. This causes the insulating layer to be exposed while causing the semiconductor layer to be divided into a plurality of semiconductor device structures each having a pair of second side surfaces. Thereafter, the supporting substrate is cut among the plurality of semiconductor device structures. This causes the supporting substrate to be divided into a plurality of partial substrates each having a pair of first side surfaces.

Thus, the supporting substrate is cut among the plurality of semiconductor device structures. Even when the supporting substrate is physically cut, therefore, a shock is inhibited from being applied to the semiconductor device structure by the cutting.

Furthermore, when the supporting substrate is cut by laser scribing, the semiconductor layer is not irradiated with a laser beam, which prevents a melt or a sublimate of the semiconductor layer from adhering to the side surface of the semiconductor device. This prevents the side surface of the partial substrate and the side surface of the semiconductor device structure from being electrically short-circuited by the melt. As a result, the yield of the semiconductor device is sufficiently improved.

When the supporting substrate is divided, the supporting substrate is cut such that the pair of second side surfaces of each of the semiconductor device structures is respectively positioned inside the pair of first side surfaces of each of the partial substrates obtained by the division.

In this case, the pair of second side surfaces of each of the semiconductor device structures and the pair of first side surfaces of each of the partial substrates are respectively spaced apart from each other by a predetermined distance in a direction perpendicular to the pair of second side surfaces of the semiconductor device structure. Furthermore, the supporting substrate is cut such that the insulating layer covers a region between the pair of first side surfaces of each of the partial substrates and the pair of second side surfaces of each of the semiconductor device structures.

Even when the melt formed by heat generated when the semiconductor device is operated adheres to the pair of first side surfaces of each of the partial substrates and the pair of second side surfaces of each of the semiconductor device structures, therefore, the side surface of the partial substrate and the side surface of the semiconductor device structure are prevented from being electrically short-circuited by the melt. As a result, defective insulation is sufficiently inhibited from occurring when the semiconductor device is operated.

Furthermore, the substrate for growth becomes easy to strip by forming the semiconductor layer on the substrate for growth with the release layer sandwiched therebetween.

(4-b)

In the above-mentioned method for manufacturing the blue-violet semiconductor laser device 100, the nitride based semiconductor layer 10 in the inter-device regions is removed before the scribe flaws parallel to the ridges Ri are formed. This eliminates the necessity of separating the nitride based semiconductor layer 10 by scribing when the scribe flaws are formed.

When diamond point scribing is performed along the scribe lines SL, therefore, a shock is prevented from being applied to the nitride based semiconductor layer 10. This inhibits the nitride based semiconductor layer 10 from being damaged. As a result, the yield of the blue-violet semiconductor laser device 100 is improved.

When laser scribing is performed along the scribe lines SL, the nitride based semiconductor layer 10 is not irradiated with a laser beam. Therefore, a melt or a sublimate of the nitride based semiconductor layer 10 is prevented from adhering to a side surface of the blue-violet semiconductor laser device 100 as a debris.

This inhibits the nitride based semiconductor layer 10 and the fusion layer 30 from being electrically short-circuited by the adhesion of the debris. As a result, defective insulation is sufficiently inhibited from occurring when the blue-violet semiconductor laser device 100 is manufactured, and the yield of the blue-violet semiconductor laser device 100 is improved.

(4-c)

In the above-mentioned blue-violet semiconductor laser device 100, in the direction perpendicular to the ridge Ri, the exposed side surfaces of the nitride based semiconductor layer 10 and the exposed side surfaces of the fusion layer 30 are spaced apart from each other by the distance D.

Even when a part of the fusion layer 30 is melted due to the effect of heat generated by lasing when the blue-violet semiconductor laser device 100 is operated, therefore, its melt is sufficiently inhibited from being detoured to the nitride based semiconductor layer 10 along a side surface of the blue-violet semiconductor laser device 100. As a result, defective insulation is sufficiently inhibited from occurring when the blue-violet semiconductor laser device 100 is operated.

(5) Specific Example and Modification of Each Constituent Element

(5-a)

Although in the present embodiment, the GaN substrate 50 is used as a nitride based semiconductor substrate for growing the nitride based semiconductor layer 10, the nitride based semiconductor substrate may be replaced with different types of substrates such as an α-SiC substrate, a GaAs substrate, a GaP substrate, an InP substrate, a Si substrate, a sapphire substrate, a spinel substrate, and a LiAlO₃ substrate. Note that it is preferable that the nitride based semiconductor substrate is used in order to obtain an AlGaInN based semiconductor layer superior in crystallinity.

(5-b)

Used as a material for the release layer 51 may be a material having a lower melting point or boiling point than that of the nitride based semiconductor layer 10 or may be a material that can be more easily decomposed than the nitride based semiconductor layer 10. Furthermore, a material that is melted more easily than the nitride based semiconductor layer 10 or a material that reacts more easily than the nitride based semiconductor layer 10 may be used.

(5-c)

The active layer 12 may have a single layer structure, or may have an SQW (Single Quantum Well) structure or an MQW (Multi Quantum Well) structure.

(5-d)

The first semiconductor layer 11 includes a first cladding layer having a higher band gap energy than that of the active layer 12.

In the first semiconductor layer 11, an optical guide layer having a higher band gap energy than that of the active layer 12 and having a lower band gap energy than that of the first cladding layer may be formed between the first cladding layer and the active layer 12. Furthermore, in the first semiconductor layer 11, a buffer layer may be formed between the first cladding layer and the release layer 5.

(5-e)

The second semiconductor layer 13 includes a second cladding layer having a higher band gap energy than that of the active layer 12.

In the second semiconductor layer 13, an optical guide layer having a higher band gap energy than that of the active layer 12 and having a lower band gap energy than that of the second cladding layer may be formed between the second cladding layer and the active layer 12.

Furthermore, in the second semiconductor layer 13, a contact layer may be formed between the electrode 19 and the second cladding layer. It is preferable that the band gap energy of the contact layer is lower than that of the second cladding layer.

(5-f)

Usable for the nitride based semiconductor layer 10 is a nitride of a Group 13 element including at least one of Ga (gallium), Al (aluminum), In (indium), Tl (thallium), and B (boron). Specifically, a nitride based semiconductor composed of AlN, InN, BN, TlN, GaN, AlGaN, InGaN, InAlGaN or their mixed crystal can be used as the nitride based semiconductor layer 10. Alternatively, the nitride based semiconductor layer 10 may be replaced with an AlGaAs based, GaInAs based, AlGaInP based, AlGaInNAs based, AlGaSb based, AlGaInAsP based, MgZnSSe based, or ZnO based semiconductor layer.

(5-g)

Although in the present embodiment, the Ge substrate 42 having conductive properties is used as a supporting substrate for the nitride based semiconductor layer 10, the supporting substrate may have conductive properties or may have insulating properties.

Usable as the supporting substrate having conductive properties is a metal substrate such as a Cu—W substrate, an Al substrate, or an Fe—Ni substrate. Furthermore, a semiconductor substrate composed of monocrystalline Si, SiC, GaAs, ZnO, or the like can be used. Furthermore, a polycrystalline AlN substrate can be also used. In addition thereto, a conductive resin film having fine particles of a conductive material such as a metal material dispersed therein may be used. Alternatively, a metal/metal oxide composite material may be used. Furthermore, a carbon/metal composite material composed of a graphite particle sinter impregnated with a metal may be used.

(5-h)

Other insulating materials such as Si₃N₄ (silicon nitride) may be used as a material for the current blocking layer 21. Other insulating materials such as Si₃N₄ may be used as a material for the insulating layer 22.

### [2] Second Embodiment

In the present embodiment, a light emitting diode that emits a light beam having a wavelength of approximately 400 nm (hereinafter abbreviated as a blue-violet LED) will be described as an example of a semiconductor device.

(1) Method for Manufacturing LED

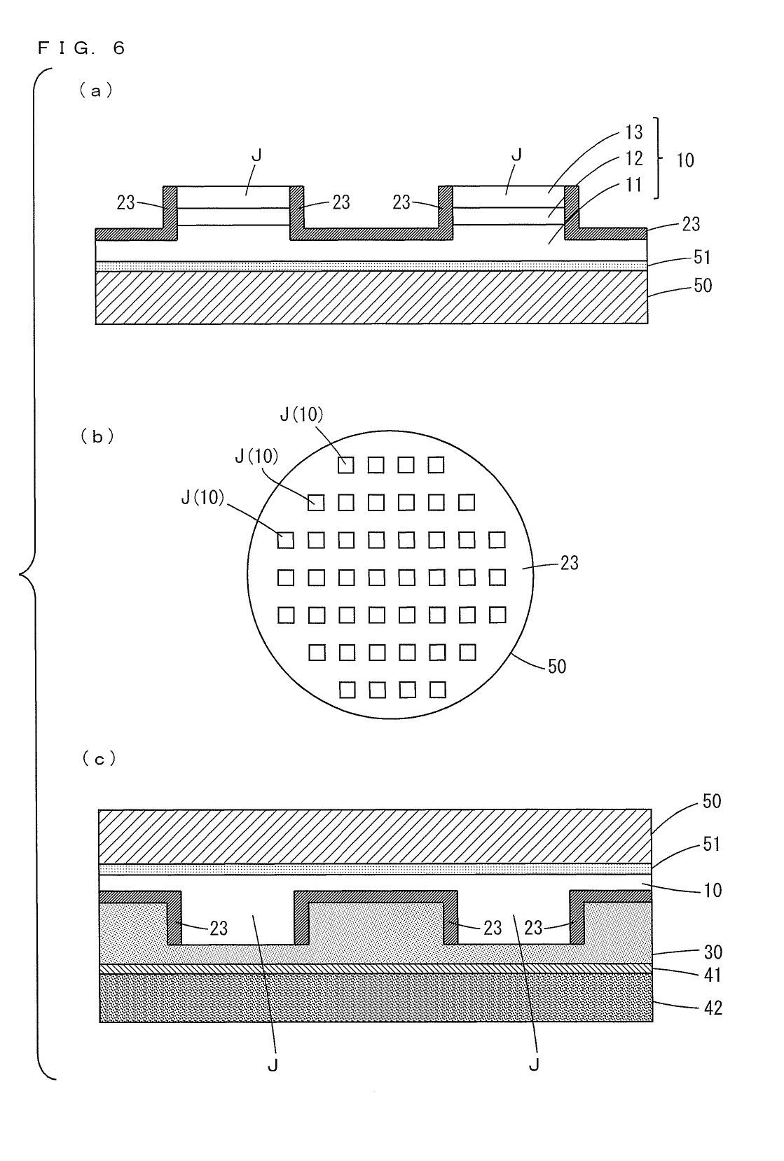

As to a method for manufacturing the blue-violet LED according to the present embodiment, the difference from the method for manufacturing the blue-violet semiconductor laser device 100 according to the first embodiment will be described. FIGS. 6 to 8 are schematic process diagrams for explaining the method for manufacturing the blue-violet LED according to the second embodiment.

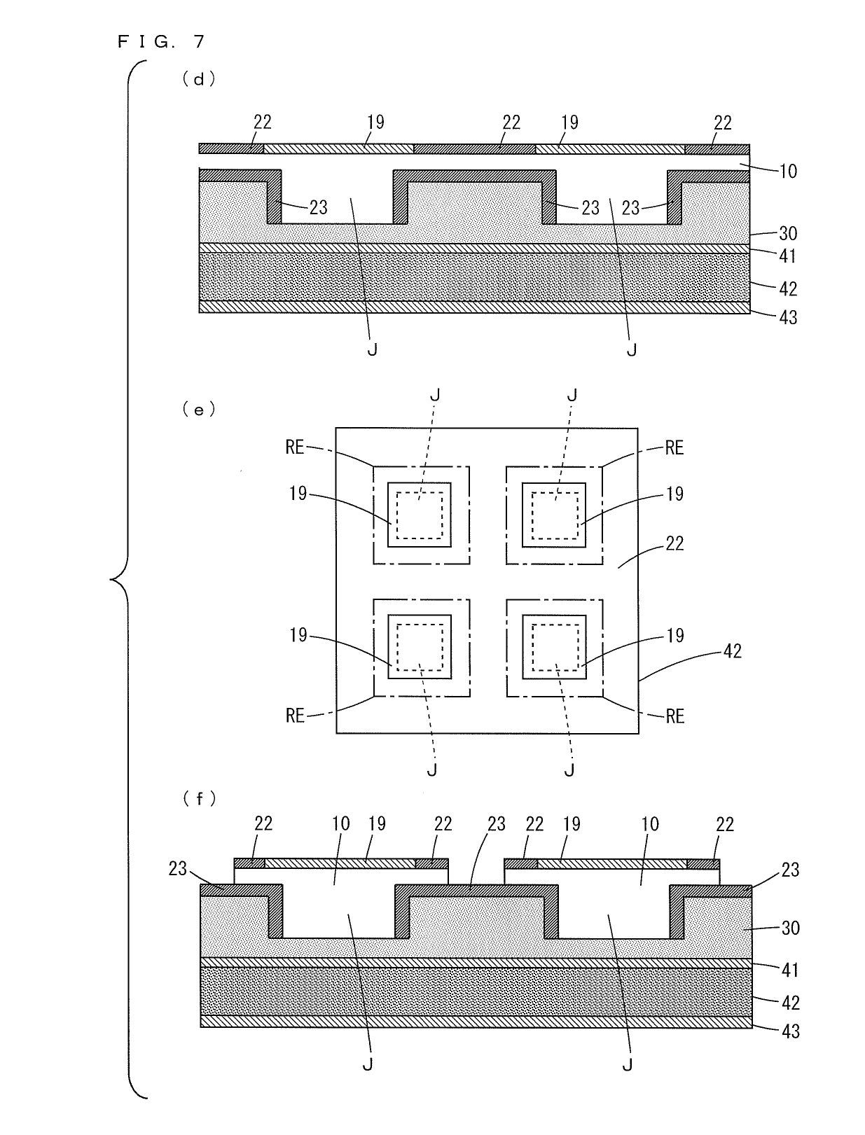

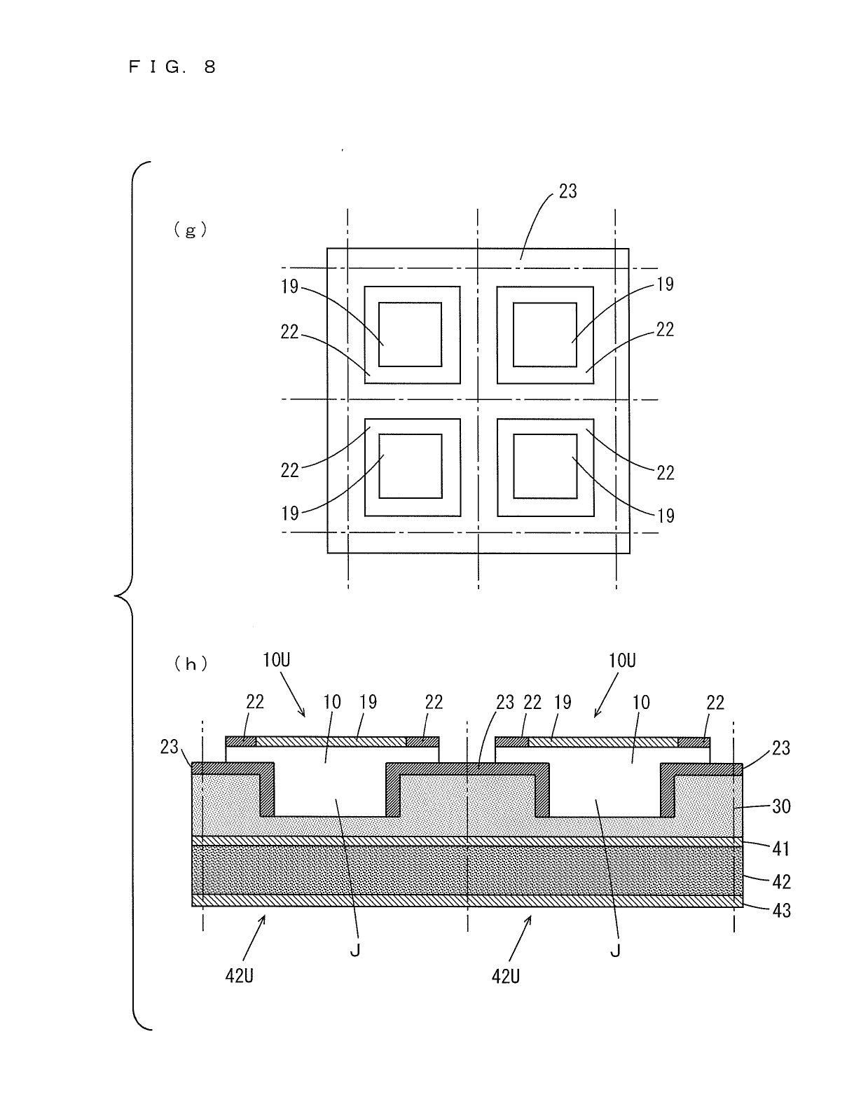

In FIGS. 6 to 8, FIGS. 6 (a) and 6 (c) are schematic sectional views of a substrate, FIG. 6 (b) is a top view of the substrate, FIGS. 7 (e) and 8 (g) are enlarged top views of the substrate, and FIGS. 7 (f) and 8 (h) are schematic sectional views of a device structure.

The blue-violet LED according to the present embodiment mainly has a configuration in which a Ge substrate 42 and a nitride based semiconductor layer 10 are affixed to each other, similarly to the blue-violet semiconductor laser device 100 according to the first embodiment.

(1-a) Nitride Based Semiconductor Layer

First, a GaN substrate 50 is prepared, and a release layer 51, a first semiconductor layer 11, an active layer 12, and a second semiconductor layer 13 are grown in this order by MOCVD, for example, on the prepared GaN substrate 50, as in the first embodiment.

A plurality of rectangular projections J are formed in the nitride based semiconductor layer 10 on the GaN substrate 50, and an insulating layer 23 is formed on an upper surface of the nitride based semiconductor layer 10 excluding an upper surface of each of the projections J and side surfaces of each of the projections J, as shown in FIGS. 6 (a) and 6 (b). The rectangular projections J in the nitride based semiconductor layer 10 are arranged over substantially the entire area of the GaN substrate 50, as shown in FIG. 6 (b). Note that a SiO₂ film is formed as the insulating layer 23 in the present embodiment.

(1-b) Affixation of Nitride Based Semiconductor Layer and Ge Substrate

On the other hand, a Ge substrate 42 is prepared, and a contact electrode 41 is formed on one surface of the Ge substrate 42, as in the first embodiment. Furthermore, a fusion layer 30 is formed on the contact electrode 41.

The nitride based semiconductor layer 10 shown in FIG. 6 (a) and the Ge substrate 42 are affixed to each other by thermocompression bonding, as shown in FIG. 6 (c).

(1-c) Separation of GaN Substrate and Formation of Electrode

Thereafter, the GaN substrate 50 is separated from the nitride based semiconductor layer 10 by irradiating the release layer 51 with a laser beam, and light-transmittable electrodes 19 and an insulating layer 22 are formed in a predetermined pattern on one surface of the nitride based semiconductor layer 10, as shown in FIG. 7 (d).

(1-d) Back Surface Electrode

A back surface electrode 43 is formed on the exposed other surface, on which the nitride based semiconductor layer 10 is not formed, of the Ge substrate 42.

(1-e) Separation of Device

Here, a region including each of the rectangular projections J and its surrounding portion having a predetermined width is referred to as a device region. The device region includes the electrode 19 above each of the projections J and its surrounding portion having a predetermined width of the insulating layer 22. Furthermore, lattice-shaped regions having a predetermined width (hereinafter referred to as inter-device regions) are set among the plurality of device regions.

Then, a resist RE is formed on each device region including the projection J (indicated by a dotted line in FIG. 7) in the nitride based semiconductor layer 10, as shown in FIG. 7 (e).

A portion of the insulating layer 22 exposed in the inter-device regions is removed by BHF (buffered HF), and RIE is made within a Cl₂ based gas atmosphere to remove the nitride based semiconductor layer 10 in the inter-device regions, and remove the resists RE such that the insulating layer 23 remains between the Ge substrate 42 and the nitride based semiconductor layer 10, as shown in FIG. 7 (f). This causes the insulating layer 23 to be exposed under the insulating layer 22 in the inter-device regions. In such a way, a plurality of semiconductor device structures 10U are produced.

Thereafter, scribe flaws reaching the Ge substrate 42 from an exposed surface of the insulating layer 23 are respectively formed at the centers of the inter-device regions by laser scribing or diamond point scribing, as indicated by one-dot and dash lines in FIGS. 8 (g) and 8 (h). Therefore, the Ge substrate 42 is cleaved along the scribe flaws using a cleavage device. In such a way, a plurality of partial substrates 42U are produced. This causes the Ge substrate 42 to be separated in a device unit composed of the semiconductor device structure 10U and the partial substrate 42U.

(2) Configuration of Blue-Violet LED

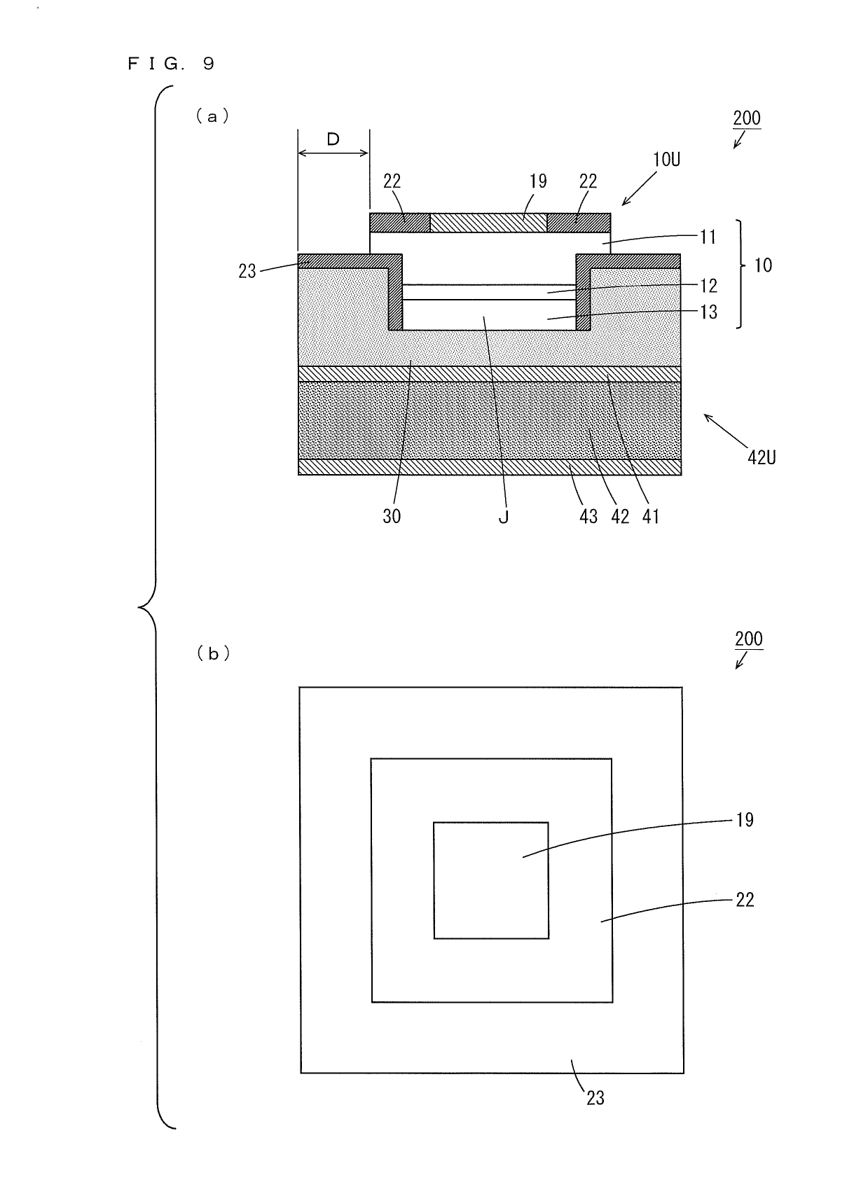

FIG. 9 is a schematic sectional view and a top view showing the blue-violet LED 200 according to the second embodiment. In the blue-violet LED 200, a voltage is applied to an area between the electrode 19 and the back surface electrode 43, so that a light beam having a wavelength of approximately 400 nm is radially emitted from the active layer 12.

In the blue-violet LED 200, the size of the nitride based semiconductor layer 10 is smaller than the size of the Ge substrate 42, as shown in FIGS. 9 (a) and 9 (b). Furthermore, the nitride based semiconductor layer 10 is positioned at the center of the Ge substrate 42.

Therefore, steps consisting of an upper surface of the insulating layer 23 around the nitride based semiconductor layer 10 and an upper surface of the insulating layer 22 on the nitride based semiconductor layer 10 are formed.

The insulating layer 23 is formed so as to cover an upper surface of the partial substrate 42U between four side surfaces of the partial substrate 42U and four side surfaces of the semiconductor device structure 10U. Furthermore, the insulating layer 23 is formed so as to extend between the Ge substrate 42 and the nitride based semiconductor layer 10.

The fusion layer 30 is formed between the Ge substrate 42 and the nitride based semiconductor layer 10. Thus, the insulating layer 23 is formed so as to extend between the fusion layer 30 and the nitride based semiconductor layer 10.

The nitride based semiconductor layer 10 has the projection J on the side of the Ge substrate 42. The active layer 12 is formed in the projection J. Furthermore, the nitride based semiconductor layer 10 includes a first semiconductor layer 11 and a second semiconductor layer 13. The second semiconductor layer 13 is provided on the side of the Ge substrate 42. At least a part of the first semiconductor layer 11 and the second semiconductor layer 13 are formed in the projection J.

The insulating layer 23 is formed on a side surface of the active layer 12. In this case, the insulating layer 23 is formed on a side surface of a junction between the first semiconductor layer 11 and the second semiconductor layer 13. That is, the insulating layer 23 is formed so as to extend in a region excluding the upper surface of the projection J.

In the present embodiment, it is preferable that the distance D between a side surface of the nitride based semiconductor layer 10 and a side surface of the fusion layer 30 is set to not less than approximately 5 μm nor more than approximately 50 μm.

(3) Correspondences Between Elements in the Claims and Parts in Embodiments

In the second embodiment, the blue-violet LED 200 is an example of a semiconductor device, the Ge substrate 42 or the partial substrate 42U is an example of a supporting substrate, the nitride based semiconductor layer 10 or the semiconductor device structure 10U is an example of a semiconductor layer, the insulating layer 23 is an example of an insulating layer, and the fusion layer 30 is an example of a fusion layer. The active layer 12 is an example of a light emitting layer, the projection J is an example of a projection, the first semiconductor layer 11 is an example of a semiconductor layer of a first conductivity type, and the second semiconductor layer 13 is an example of a semiconductor layer of a second semiconductor layer.

Furthermore, the GaN substrate 50 is an example of a substrate for growth, and the release layer 51 is an example of a release layer.

(4) Effect of Second Embodiment

(4-a)

In the semiconductor device according to the present embodiment, the supporting substrate has a supporting surface, a pair of first side surfaces, and a pair of third side surfaces crossing the pair of first side surfaces. The semiconductor layer is provided on the supporting surface of the supporting substrate. The semiconductor layer has a pair of second side surfaces and a pair of fourth side surfaces crossing the pair of second side surfaces.

The pair of second side surfaces of the semiconductor layer is respectively positioned inside the pair of first side surfaces of the supporting substrate. This causes the pair of second side surfaces of the semiconductor layer and the pair of first side surfaces of the supporting substrate to be respectively spaced apart from each other by a predetermined distance in a direction perpendicular to the pair of second side surfaces of the semiconductor layer. Furthermore, the insulating layer is formed so as to cover a region of the supporting surface between the pair of first side surfaces of the supporting substrate and the pair of second side surfaces of the semiconductor layer. Even when a melt formed by heat generated when the semiconductor device is operated adheres to the pair of first side surfaces of the supporting substrate and the pair of second side surfaces of the semiconductor layer, therefore, the side surface of the supporting substrate and the side surface of the semiconductor layer are prevented from being electrically short-circuited by the melt. As a result, defective insulation is sufficiently inhibited from occurring when the semiconductor device is operated.

Furthermore, the pair of fourth side surfaces of the semiconductor layer is respectively positioned inside the pair of third side surfaces of the supporting substrate. This causes the pair of fourth side surfaces of the semiconductor layer and the pair of third side surfaces of the supporting substrate to be respectively spaced apart from each other by a predetermined distance in a direction perpendicular to the pair of fourth side surfaces of the semiconductor layer. Furthermore, the insulating layer is formed so as to cover a region of the supporting surface between the pair of third side surfaces of the supporting substrate and the pair of fourth side surfaces of the semiconductor layer. Even when a melt formed by heat generated when the semiconductor device is operated adheres to the pair of third side surfaces of the supporting substrate and the pair of fourth side surfaces of the semiconductor layer, therefore, the side surface of the supporting substrate and the side surface of the semiconductor layer are prevented from being electrically short-circuited by the melt. As a result, defective insulation is sufficiently inhibited from occurring when the semiconductor device is operated.

The semiconductor device further includes the fusion layer formed between the supporting substrate and the semiconductor layer. In this case, even when a part of the fusion layer is melted by heat generated when the semiconductor device is operated, and the melt adheres to the pair of first side surfaces of the supporting substrate and the pair of second side surfaces of the semiconductor layer, the side surface of the supporting substrate and the side surface of the semiconductor layer are prevented from being electrically short-circuited by the melt. Furthermore, even when a part of the fusion layer is melted by heat generated when the semiconductor device is operated, and the melt adheres to the pair of third side surfaces of the supporting substrate and the pair of fourth side surfaces of the semiconductor layer, the side surface of the supporting substrate and the side surface of the semiconductor layer are prevented from being electrically short-circuited by the melt. As a result, defective insulation is sufficiently inhibited from occurring when the semiconductor device is operated.

Since the insulating layer is formed so as to extend between the fusion layer and the semiconductor layer, the fusion layer is prevented from being detoured along the side surface of the semiconductor device.

The semiconductor layer includes a light emitting layer that emits a light beam. In this case, even when a melt formed by heat generated by the light emitting layer when the semiconductor device is operated adheres to the pair of first side surfaces of the supporting substrate and the pair of second side surfaces of the semiconductor layer, the side surface of the supporting substrate and the side surface of the semiconductor layer are prevented from being electrically short-circuited by the melt. Even when the melt formed by heat generated by the light emitting layer when the semiconductor device is operated adheres to the pair of third side surfaces of the supporting substrate and the pair of fourth side surfaces of the semiconductor layer, the side surface of the supporting substrate and the side surface of the semiconductor layer are prevented from being electrically short-circuited by the melt. As a result, defective insulation is sufficiently inhibited from occurring when the light beam is emitted.

Since the insulating layer is formed on a side surface of the light emitting layer, a leak current flowing after being detoured along the side surface of the light emitting layer can be restrained.

The semiconductor layer has a projection on the side of the supporting substrate, and the light emitting layer is formed in the projection. Furthermore, the semiconductor layer includes a semiconductor layer of a first conductivity type and a semiconductor layer of a second conductivity type, on the side of the supporting substrate, on the semiconductor layer of a first conductivity type, and the insulating layer is formed on a side surface of a junction between the semiconductor layer of a first conductivity type and the semiconductor layer of a second conductivity type. In this case, a leak current flowing after being detoured along the junction between the semiconductor layer of a first conductivity type and the semiconductor layer of a second conductivity type through the side surface of the junction between the semiconductor layer of a first conductivity type and the semiconductor layer of a second conductivity type can be restrained.

The semiconductor layer includes a nitride based semiconductor. In this case, the heat resistance of the semiconductor device is improved.

In the method for manufacturing the semiconductor device according to the present embodiment, the semiconductor layer is formed on the substrate for growth, the insulating layer is formed on a predetermined region of the semiconductor layer, and the substrate for growth and the supporting substrate are affixed to each other with the insulating layer sandwiched therebetween. Then, the substrate for growth is separated from the semiconductor layer, and the semiconductor layer in a partial region is removed. This causes the insulating layer to be exposed while causing the semiconductor layer to be divided into a plurality of semiconductor device structures each having a pair of second side surfaces and a pair of fourth side surfaces. Thereafter, the supporting substrate is cut among the plurality of semiconductor device structures. This causes the supporting substrate to be divided into the plurality of partial substrates each having a pair of first side surfaces and a pair of third side surfaces.

Thus, the supporting substrate is cut among the plurality of semiconductor device structures. Even when the supporting substrate is physically cut, therefore, a shock is inhibited from being applied to the semiconductor device structure by the cutting.

Furthermore, when the supporting substrate is cut by laser scribing, the semiconductor layer is not irradiated with a laser beam, which prevents a melt or a sublimate of the semiconductor layer from adhering to the side surface of the semiconductor device. This prevents the side surface of the partial substrate and the side surface of the semiconductor device structure from being electrically short-circuited by the melt. As a result, the yield of the semiconductor device is sufficiently improved.

When the supporting substrate is divided, the supporting substrate is cut such that the pair of second side surfaces of each of the semiconductor device structures is respectively positioned inside the pair of first side surfaces of each of the partial substrates obtained by the division. Furthermore, the supporting substrate is cut such that the pair of fourth side surfaces of each of the semiconductor device structures is respectively positioned inside the pair of third side surfaces of each of the partial substrates obtained by the division.

In this case, the pair of second side surfaces of each of the semiconductor device structures and the pair of first side surfaces of each of the partial substrates are respectively spaced apart from each other by a predetermined distance in a direction perpendicular to the pair of second side surfaces of the semiconductor device structure. The pair of fourth side surfaces of each of the semiconductor device structures and the pair of third side surfaces of each of the partial substrates are respectively spaced apart from each other by a predetermined distance in a direction perpendicular to the pair of fourth side surfaces of the semiconductor device structure. The supporting substrate is cut such that the insulating layer covers a region between the pair of first side surfaces of each of the partial substrates and the pair of second side surfaces of each of the semiconductor device structures. Furthermore, the supporting substrate is cut such that the insulating layer covers a region between the pair of third side surfaces of each of the partial substrates and the pair of fourth side surfaces of each of the semiconductor device structures.

Even when the melt formed by heat generated when the semiconductor device is operated adheres to the pair of first side surfaces of each of the partial substrates and the pair of second side surfaces of each of the semiconductor device structures, therefore, the side surface of the partial substrate and the side surface of the semiconductor device structure are prevented from being electrically short-circuited by the melt. Even when the melt formed by heat generated when the semiconductor device is operated adheres to the pair of third side surfaces of each of the partial substrates and the pair of fourth side surfaces of each of the semiconductor device structures, therefore, the side surface of the partial substrate and the side surface of the semiconductor device structure are prevented from being electrically short-circuited by the melt. As a result, defective insulation is sufficiently inhibited from occurring when the semiconductor device is operated.

Furthermore, the substrate for growth becomes easy to strip by forming the semiconductor layer on the substrate for growth with the release layer sandwiched therebetween.

(4-b)

In the above-mentioned method for manufacturing the blue-violet LED 200, the nitride based semiconductor layer 10 in the inter-device regions is entirely removed before the scribe flaws are formed. This eliminates the necessity of separating the nitride based semiconductor layer 10 by scribing when the scribe flaws are formed.

When diamond point scribing is performed along scribe lines, therefore, a shock is prevented from being applied to the nitride based semiconductor layer 10. This prevents the nitride based semiconductor layer 10 from being damaged. As a result, the yield of the blue-violet LED 200 is reliably improved.

When laser scribing is performed along scribe lines, the nitride based semiconductor layer 10 is not irradiated with a laser beam. Therefore, a melt or a sublimate of the nitride based semiconductor layer 10 is prevented from adhering to a side surface of the blue-violet LED 200 as a debris.

This inhibits the nitride based semiconductor layer 10 and the fusion layer 30 from being electrically short-circuited by the adhesion of the debris. As a result, defective insulation is sufficiently inhibited from occurring when the blue-violet LED 200 is manufactured, and the yield of the blue-violet LED 200 is improved.

(4-c)

In the above-mentioned blue-violet LED 200, the side surfaces (outer peripheral surface) of the nitride based semiconductor layer 10 is positioned inside side surfaces (outer peripheral surface) of the Ge substrate 42. Thus, the side surfaces of the nitride based semiconductor layer 10 and the exposed side surfaces of the fusion layer 30 are spaced apart from each other by the distance D.

Even when a part of the fusion layer 30 is melted due to the effect of heat when the blue-violet LED 200 is operated, therefore, its melt is sufficiently inhibited from being detoured to the nitride based semiconductor layer 10 along a side surface of the blue-violet LED 200. As a result, defective insulation is sufficiently inhibited from occurring when the blue-violet LED 200 is operated.

(5) Specific Example and Modification of Each Constituent Element

The specific example and the modification described in the first embodiment are also applicable to each of constituent elements in the blue-violet LED 200 according to the present embodiment.

Note that in the blue-violet LED 200, an optical guide layer need not be formed in the first semiconductor layer 11 and the second semiconductor layer 13 in the nitride based semiconductor layer 10.

### [3] Manufacturing Test of Device

### (1) Inventive Examples

The inventors manufactured semiconductor devices in inventive examples 1 to 3, described below, by the method for manufacturing the semiconductor device according to the first or second embodiment, and operated each of the manufactured semiconductor devices, to confirm the yield thereof.

### (1-a) Inventive Example 1

The inventors manufactured the blue-violet semiconductor laser device 100 shown in FIG. 5 by the manufacturing method described in the first embodiment as the semiconductor device in the inventive example 1. When the blue-violet semiconductor laser device 100 in the inventive example 1 was manufactured, scribe flaws were formed in the Ge substrate 42 by diamond point scribing.

Manufactured 20 blue-violet semiconductor laser devices 100 were respectively operated. In this case, 16 of the 20 blue-violet semiconductor laser devices 100 respectively emitted light beams. The yield was 80%.

### (1-b) Inventive Example 2

The inventors manufactured the blue-violet semiconductor laser device 100 shown in FIG. 5 by the manufacturing method described in the first embodiment as the semiconductor device in the inventive example 2. When the blue-violet semiconductor laser device 100 in the inventive example 2 was manufactured, scribe flaws were formed in the Ge substrate 42 by laser scribing.

Manufactured 30 blue-violet semiconductor laser devices 100 were respectively operated. In this case, 26 of the 30 blue-violet semiconductor laser devices 100 respectively emitted light beams. The yield was 87%.

### (1-c) Inventive Example 3

The inventors manufactured the blue-violet LED 200 shown in FIG. 9 by the manufacturing method described in the second embodiment as the semiconductor device in the inventive example 3. When the blue-violet LED 200 in the inventive example 3 was manufactured, scribe flaws were formed in the Ge substrate 42 by laser scribing.

Manufactured 43 blue-violet LEDs 200 were respectively operated. In this case, 38 of the 43 blue-violet LEDs 200 respectively emitted light beams. The yield was 88%.

### (2) Comparative Examples

The inventors manufactured semiconductor devices in comparative examples 1 to 3 by a method, described below, and operated each of the manufactured semiconductor devices, to confirm the yield thereof.

### (2-a) Comparative Example 1

The inventors manufactured a blue-violet semiconductor laser device in the comparative example 1 by the same manufacturing method as the method for manufacturing the blue-violet semiconductor laser device 100 in the inventive example 1 except that a nitride based semiconductor layer 10 in inter-device regions was not removed before scribe flaws were formed in a Ge substrate 42 as the semiconductor device in the comparative example 1.

Manufactured 16 blue-violet semiconductor laser devices were respectively operated. In this case, 10 of the 16 blue-violet semiconductor laser devices respectively emitted light beams. The yield was 63%.

### (2-b) Comparative Example 2

The inventors manufactured a blue-violet semiconductor laser device in the comparative example 2 by the same manufacturing method as the method for manufacturing the blue-violet semiconductor laser device 100 in the inventive example 2 except that a nitride based semiconductor layer 10 in inter-device regions was not removed before scribe flaws were formed in a Ge substrate 42 as the semiconductor device in the comparative example 2.

Manufactured 20 blue-violet semiconductor laser devices were respectively operated. In this case, 12 of the 20 blue-violet semiconductor laser devices 100 respectively emitted light beams. The yield was 60%.

### (2-c) Comparative Example 3

The inventors manufactured a blue-violet LED in the comparative example 3 by the same manufacturing method as the method for manufacturing the blue-violet LED 200 in the inventive example 3 except that a nitride based semiconductor layer 10 in inter-device regions was not removed before scribe flaws were formed in a Ge substrate 42 as the semiconductor device in the comparative example 3.

Manufactured 26 blue-violet LEDs were respectively operated. In this case, 13 of the 26 blue-violet LEDs 13 respectively emitted light beams. The yield was 50%.

### (3) Evaluation

(3-a)

Comparison between the inventive example 1 and the comparative example 1 showed that the yield of the blue-violet semiconductor laser device 1 in the inventive example 1 was higher than the yield of blue-violet semiconductor laser device in the comparative example 1. This clarified that the yield of the semiconductor device was improved by previously removing the nitride based semiconductor layer 10 in the inter-device regions before the scribe flaws are formed.

(3-b)

Comparison between the inventive example 2 and the comparative example 2 showed that the yield of the blue-violet semiconductor laser device 2 in the inventive example 2 was higher than the yield of blue-violet semiconductor laser device in the comparative example 2. This clarified that the yield of the semiconductor device was improved by previously removing the nitride based semiconductor layer 10 in the inter-device regions before the scribe flaws were formed.

The reason why the yield of the blue-violet semiconductor laser device in the comparative example 2 was lower than the yield of the blue-violet semiconductor laser device 100 in the inventive example 2 is conceivably that a debris generated by laser scribing adhered over the nitride based semiconductor laser 10 to a fusion layer 30 on a side surface of the blue-violet semiconductor laser device so that defective insulation occurred between the nitride based semiconductor layer 10 and the fusion layer 30.

(3-c)

Comparison between the inventive example 3 and the comparative example 3 showed that the yield of the blue-violet LED 200 in the inventive example 3 was higher than the yield of blue-violet LED in the comparative example 3. This clarified that the yield of the semiconductor device was improved by previously removing the nitride based semiconductor layer 10 in the inter-device regions before the scribe flaws were formed.

The reason why the yield of the blue-violet LED in the comparative example 3 was lower than the yield of the blue-violet LED in the inventive example 3 is conceivably that a debris generated by laser scribing adhered over the nitride based semiconductor layer 10 to a fusion layer 30 on a side surface of the blue-violet LED so that defective insulation occurred between the nitride based semiconductor layer 10 and the fusion layer 30.

(3-d)

Comparison between the inventive example 1 and the inventive example 2 showed that the yield of the blue-violet semiconductor laser device 2 in the inventive example 2 was higher than the yield of the blue-violet semiconductor laser device 100 in the inventive example 1. The reason is conceivably that a shock applied to the nitride based semiconductor layer 10 when laser scribing was performed was smaller than a shock applied to the nitride based semiconductor layer 10 when diamond point scribing was performed.

### [4] Another Embodiment

The present invention is applicable to not only a semiconductor laser device and an LED but also various types of semiconductor devices such as a transistor, a diode, and a light receiving element.

### (5) Correspondences Between Elements in the Claims and Parts in Embodiments

In the following paragraphs, non-limiting examples of correspondences between various elements recited in the claims below and those described above with respect to various preferred embodiments of the present invention are explained.

In the embodiments described above, the surface, to which the nitride based semiconductor layer 10 is affixed, of the Ge substrate 42 is an example of a supporting surface, the opposed pairs of side surfaces of the partial substrate 42U are examples of a pair of first side surfaces and a pair of third side surfaces, the Ge substrate 42 is an example of a supporting substrate, the nitride based semiconductor layer 10 is an example of a semiconductor layer, the opposed pairs of side surfaces of the semiconductor device structure 10U are examples of a pair of second side surfaces and a pair of fourth side surfaces, the current blocking layer 21 and the insulating layer 23 are examples of an insulating layer, the active layer 12 is an example of alight emitting layer, the semiconductor device structure 10U shown in FIGS. 4 and 5 is an example of a cavity, and the GaN substrate 50 is an example of a substrate for growth.

As the elements recited in the claims, various other elements having the configurations or functions as recited in the claims can be also used.

While preferred embodiments of the present invention have been described above, it is to be understood that variations and modifications will be apparent to those skilled in the art without departing the scope and spirit of the present invention. The scope of the present invention, therefore, is to be determined solely by the following claims.

1.-20. (canceled)

21. A semiconductor device comprising:
a supporting substrate having a supporting surface and a pair of first side surfaces;
a semiconductor layer provided on said supporting surface of said supporting substrate and having a pair of second side surfaces respectively positioned inside said pair of first side surfaces of said supporting substrate;
an insulating layer formed so as to cover a region of said supporting surface between said pair of first side surfaces of said supporting substrate and said pair of second side surfaces of said semiconductor layer; and
a metal layer formed between said supporting substrate and said semiconductor layer and between said supporting substrate and said insulating layer, wherein
said insulating layer is formed so as to extend between said metal layer and said semiconductor layer.

22. The semiconductor device according to claim 21, wherein said semiconductor layer includes a light emitting layer that emits a light beam.

23. The semiconductor device according to claim 22, wherein said insulating layer is formed on a side surface of said light emitting layer.

24. The semiconductor device according to claim 22, wherein said semiconductor layer has a projection on the side of said supporting substrate, and said light emitting layer is formed in said projection.

25. The semiconductor device according to claim 21, wherein
said semiconductor layer includes a semiconductor layer of a first conductivity type and a semiconductor layer of a second conductivity type, on the side of said supporting substrate, on said semiconductor layer of a first conductivity type, and
said insulating layer is formed on a side surface of a junction between said semiconductor layer of a first conductivity type and said semiconductor layer of a second conductivity type.

26. The semiconductor device according to claim 21, wherein
said semiconductor layer has a projection on the side of said supporting substrate,
said semiconductor layer includes a semiconductor layer of a first conductivity type and a semiconductor layer of a second conductivity type, on the side of said supporting substrate, on said semiconductor layer of a first conductivity type, and
said projection includes said semiconductor layer of a first conductivity type and said semiconductor layer of a second conductivity type.

27. The semiconductor device according to claim 21, wherein said semiconductor layer includes a light emitting layer that emits a light beam, and
said light emitting layer includes a cavity that performs lasing.

28. The semiconductor device according to claim 27, wherein
said semiconductor layer includes a second semiconductor layer, on the side of said supporting substrate, on said light emitting layer,
said second semiconductor layer has a projection and flat portions on both side of said projection, and
said insulating layer is formed on a side surface of said projection and said flat portions, excluding an upper surface of said projection.

29. The semiconductor device according to claim 21, wherein
said supporting substrate further has a pair of third side surfaces crossing said pair of first side surfaces,
said semiconductor layer further has a pair of fourth side surfaces crossing said pair of second side surfaces and respectively positioned inside said pair of third side surfaces of said supporting substrate, and
said insulating layer is formed so as to cover a region of said supporting surface between said pair of third side surface of said supporting substrate and said pair of fourth side surfaces of said semiconductor layer.

30. The semiconductor device according to claim 21, wherein said semiconductor layer includes a nitride based semiconductor.

31. The semiconductor device according to claim 21, wherein said supporting substrate is a germanium substrate.

32. The semiconductor device according to claim 21, wherein said insulating layer is composed of silicon oxide or silicon nitride.

33. The semiconductor device according to claim 21, wherein said metal layer is composed of any of a solder composed of gold and tin, a solder composed of gold and germanium, and a conductive paste composed of silver.

34. The semiconductor device according to claim 24, wherein said projection is formed in a striped shape.
